(19) United States
(12) Patent Application Publication
(10) Pub. No.: US 2016/0293259 A1
(43) Pub. Date: Oct. 6, 2016

(54) SEMICONDUCTOR APPARATUS AND OPERATING METHOD THEREOF

(71) Applicant: SK Hynix Inc., Gyeonggi-do (KR)

(72) Inventor: Young Gyun KIM, Gyeonggi-do (KR)

(21) Appl. No.: 14/815,078

(22) Filed: Jul. 31, 2015

(30) Foreign Application Priority Data
Mar. 30, 2015 (KR) 10-2015-0044499

(51) Int. Cl. G11C 16/12; G11C 16/34; G11C 16/26

(52) U.S. Cl. CPC G11C 16/12; G11C 16/26; G11C 16/3459

(57) ABSTRACT

A nonvolatile memory apparatus includes a plurality of memory cells coupled to a word line and respectively coupled to different bit lines, and a control block configured to apply one or more program voltages to the word line in a program loop, and increase the one or more program voltages in increments each time of the program loop is repeated, wherein at least one of the increments is different.

### CROSS-REFERENCES TO RELATED APPLICATION

The present application claims priority under 35 U.S.C. §119(a) to Korean application number 10-2015-0044499, filed on Mar. 30, 2015, in the Korean Intellectual Property Office, which is incorporated herein by reference in its entirety.

### BACKGROUND

1. Technical Field

Various embodiments generally relate to a semiconductor apparatus and, more particularly, to a nonvolatile memory apparatus.

2. Related Art

A semiconductor memory device may be used to store data. Semiconductor memory devices may be divided into nonvolatile and volatile memory devices.

Nonvolatile memory devices may retain data stored therein even without a constant power source. Nonvolatile memory devices include flash memory devices such as NAND or NOR flash memory, Ferroelectrics Random Access Memory (FeRAM), Phase-Change Random Access Memory (PCRAM), Magnetoresistive Random Access Memory (MRAM) or Resistive Random Access Memory (ReRAM).

Volatile memory devices cannot retain their data without a constant source of power. Volatile memory devices include Static Random Access Memory (SRAM) and Dynamic Random Access Memory (DRAM). Volatile memory devices are generally used as buffer memory devices, cache memory devices, or working memory devices in data processing systems, due to their relatively high processing speed.

### SUMMARY

In an embodiment of the present invention, a nonvolatile memory apparatus may include a plurality of memory cells coupled to a selected word line and respectively coupled to different bit lines, and a control block suitable for applying one or more program voltages to the selected word line in a program loop, and increasing the one or more program voltages incrementally each time the program loop is repeated, wherein the increments are different.

In an embodiment of the present invention, a method for operating a nonvolatile memory apparatus may include receiving a program command for a plurality of memory cells coupled to a selected word line and respectively coupled to different bit lines, and performing a program loop by sequentially applying one or more program voltages to the selected word line, wherein the one or more program voltages are increased incrementally each time the program loop is repeated, and wherein the increments are different.

In an embodiment of the present invention, a nonvolatile memory apparatus may include a plurality of memory cells coupled to a selected word line and respectively coupled to different bit lines, and a control block suitable for applying one or more program voltages to the selected word line in a program loop, and programming the plurality of memory cells to form one or more threshold voltage distributions depending on data stored therein, wherein the one or more threshold voltage distributions have different widths.

### BRIEF DESCRIPTION OF THE DRAWINGS

FIG. 1 is a block diagram illustrating a nonvolatile memory apparatus in accordance with an embodiment of the present invention.

FIG. 2 is a circuit diagram illustrating a memory block shown in FIG. 1.

FIGS. 3A and 3B are diagrams to assist in the explanation of changes in threshold voltage distributions of memory cells due to a program operation.

FIG. 4 is a graph illustrating the magnitude of program and verification voltages applied to a selected word line, over time, when a program operation is performed in accordance with an embodiment of the present invention.

FIG. 5 is a table arranging the voltages applied to the selected word line and bit lines when the program operation is performed in accordance with an embodiment of the present invention.

FIG. 6 is a diagram to assist in the explanation of a method for verifying target memory cells.

FIG. 7 is a graph illustrating the magnitude of program and verification voltages applied to a selected word line, over time, when a program operation is performed in accordance with an embodiment of the present invention.

FIG. 8 is a table arranging the voltages applied to the selected word line and bit lines when the program operation is performed in accordance with an embodiment of the present invention.

FIG. 9 is a graph illustrating the magnitude of program and verification voltages applied to a selected word line, over time, when a program operation is performed in accordance with an embodiment of the present invention.

FIG. 10 is a table arranging the voltages applied to the selected word line and bit lines when the program operation is performed in accordance with an embodiment of the present invention.

FIG. 11 is a flow chart to assist in the explanation of a method for operating a nonvolatile memory apparatus in accordance with an embodiment of the present invention.

FIG. 12 is a block diagram illustrating a data processing system including the nonvolatile memory apparatus in accordance with an embodiment of the present invention.

FIGS. 13A to 13D are diagrams to assist in the explanation of the effects of the embodiments of the present invention.

### DETAILED DESCRIPTION

Hereinafter, a data storage device and an operating method thereof according to the present invention will be described with reference to the accompanying drawings through exemplary embodiments of the present invention. The present invention may, however, be embodied in different forms and should not be construed as being limited to the embodiments set forth herein. Rather, these embodiments are provided to describe the present invention in detail to the extent that a person skilled in the art to which the invention pertains can enforce the technical concepts of the present invention.

It is to be understood that embodiments of the present invention are not limited to the particulars shown in the drawings, that the drawings are not necessarily to scale and, in some instances, proportions may have been exaggerated in order to more clearly depict certain features of the invention. While particular terminology is used, it is to be appreciated that the terminology is for describing particular embodiments only and is not intended to limit the scope of the present invention.

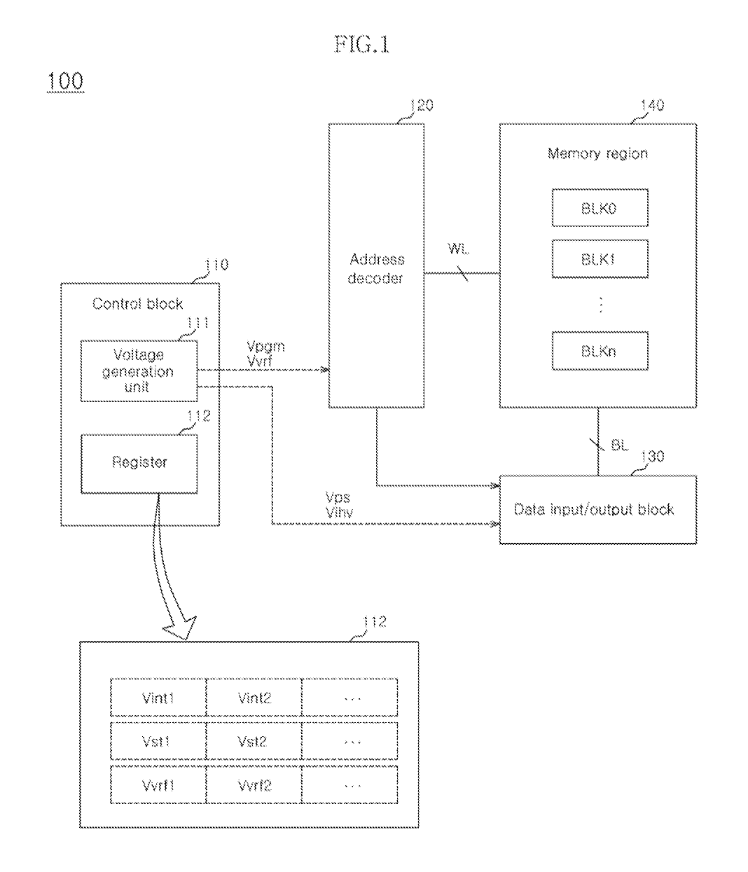

FIG. 1 is a block diagram illustrating a nonvolatile memory apparatus 100 in accordance with an embodiment of the present invention.

The nonvolatile memory apparatus 100 may include a control block 110, an address decoder 120, a data input/output block 130, and a memory region 140.

The control block 110 may perform a program operation for a selected word line of the memory region 140 in response to an access command transmitted from an external device, for example, a program command. The control block 110 may perform the program operation by repeatedly performing a program loop according to an ISPP (incremental step pulse program) scheme. The program loop may include a program voltage application process and a verification process. When performing the program loop, the control block 110 performs the program voltage application process of sequentially applying one or more program voltages Vpgm to a selected word line and the verification process of sensing bit lines BL while sequentially applying one or more verification voltages Vvrf to the selected word line. In this regard, the control block 110 may repeatedly perform the program loop based on a result of performing the verification process.

The control block 110 may increase the one or more program voltages Vpgm by respective corresponding increment values, each time the program loop is repeated. According to an embodiment, the one or more program voltages Vpgm may respectively correspond to one or more threshold voltage distributions which are formed by the target memory cells coupled to the selected word line, based on data to be stored in the target memory cells. According to an embodiment, the increment values corresponding to the one or more program voltages Vpgm may be nonuniform. Accordingly, the threshold voltage distributions to be formed by the target memory cells may have nonuniform widths.

The control block 110 may include a voltage generation unit 111 and a register 112.

The voltage generation unit 111 may generate voltages of various values to be applied to the memory region 140 through the address decoder 120 and the data input/output block 130 when the program operation is performed, for example, the program voltages Vpgm, the verification voltages Vvrf, a program permission voltage Vps and a program inhibition voltage Vihv.

The register 112 may store the values of the various voltages generated by the voltage generation unit 111. For example, the register 112 may store initial values Vint1, Vint2, . . . of the one or more program voltages Vpgm to be applied to the memory region 140 when the program loop is initially performed. Also, the register 112 may store increment values Vst1, Vst2, . . . respectively corresponding to the one or more program voltages Vpgm, for increasing the respective program voltages Vpgm each time the program loop is repeatedly performed. Further, the register 112 may store verification voltages Vvrf1, Vvrf2, . . . to be applied to the memory region 140 when the program loop is performed.

The address decoder 120 may decode the row address and the column address included in the program command. The address decoder 120 may drive the word line selected among word lines WL by the program voltages Vpgm and the verification voltages Vvrf based on a decoding result of the row address. The address decoder 120 may control the data input/output block 130 such that the bit lines BL are driven by the program permission voltage Vps and the program inhibition voltage Vihv based on a decoding result of the column address.

The data input/output block 130 may transmit the data transmitted from the external device, to the memory region 140 through the bit lines BL. The data input/output block 130 may transmit the data read from the memory region 140 through the bit lines BL, to the external device.

The memory region 140 may include memory cell arrays each of which is constructed by a plurality of memory cells. Each memory cell array may be constructed, for example, 2-dimensionally or 3-dimensionally. The memory region 140 may include a plurality of memory blocks BLK0 to BLKn.

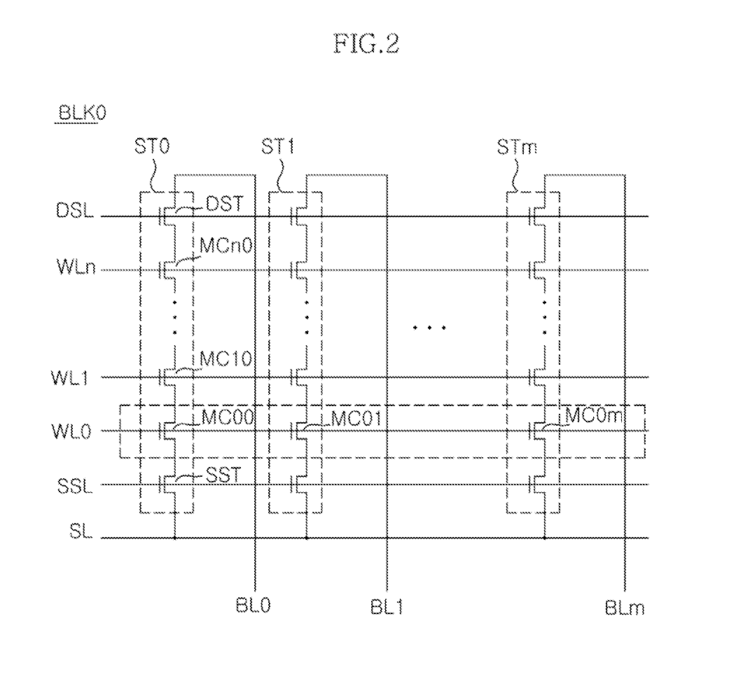

FIG. 2 is a circuit diagram illustrating the memory block BLK0 shown in FIG. 1. The memory blocks BLK0 to BLKn shown in FIG. 1 may be configured in substantially the same way as the memory block BLK0. FIG. 2 illustrates the memory block BLK0 which is configured as, for example, a 2-dimensional array. However, it is to be noted that the embodiment is not limited to such an example and the memory block BLK0 may be configured as, for example, a 3-dimensional array.

The memory block BLK0 may include strings ST0 to STm. The strings ST0 to STm may be coupled between respective bit lines BL0 to BLm and a source line SL. Because the configurations of the strings ST0 to STm are substantially the same, the configuration of the string ST0 will be described as an example. The string ST0 may be coupled between the bit line BL0 and the source line SL. The string ST0 may include a drain select transistor DST, a source select transistor SST, and a plurality of memory cells MC00 to MCn0. The drain select transistor DST may include a gate which is coupled to a drain select line DSL and a drain which is coupled to the bit line BL0. The source select transistor SST may include a gate which is coupled to a source select line SSL and a source which is coupled to the source line SL. The plurality of memory cells MC00 to MCn0 may be coupled in series between the drain select transistor DST and the source select transistor SST. The plurality of memory cells MC00 to MCn0 may respectively correspond to word lines WL0 to WLn. Each of the plurality of memory cells MC00 to MCn0 may include a gate which is coupled to a corresponding word line.

Data may be stored in a memory cell, as the charge in a floating gate, as a predetermined program voltage is applied to the gate of the memory cell. Different data may be stored in the memory cell depending on the amount of the charge in the floating gate. The size of the charge accumulated in the floating gate may be controlled by the magnitude of the program voltage applied to the gate.

Memory cells may be distinguished by the number of bits stored in each cell. For example, memory cells may be distinguished as single level cells each of which stores 1 bit and multi-level cells each of which stores at least 2 bits.

A page may be a unit on which a program operation is performed for the memory region 140. In other words, the memory region 140 may be programmed on a page basis. A page may be accessed by driving a corresponding word line.

When each of memory cells MC00 to MC0m coupled to one word line, for example, the word line WL0, stores 1 bit, the word line WL0 may correspond to one page.

When each of memory cells MC00 to MC0m coupled to one word line, for example, the word line WL0, stores 2-bit data, that is, LSB (least significant bit) data and MSB (most significant bit) data, the word line WL0 may correspond to two pages, that is, an LSB page and an MSB page. It may be seen that the LSB data and the MSB data stored in the memory cells MC00 to MC0m coupled to the word line WL0 are stored in the LSB page and the MSB page, respectively.

When each of memory cells MC00 to MC0m coupled to one word line, for example, the word line WL0, stores 3-bit data, that is, LSB (least significant bit) data, CSB (central significant bit) data and MSB (most significant bit) data, the word line WL0 may correspond to three pages, that is, an LSB page, a CSB page and an MSB page. It may be seen that the LSB data, the CSB data, and the MSB data stored in the memory cells MC00 to MC0m coupled to the word line WL0 are stored in the LSB page, the CSB page and the MSB page, respectively.

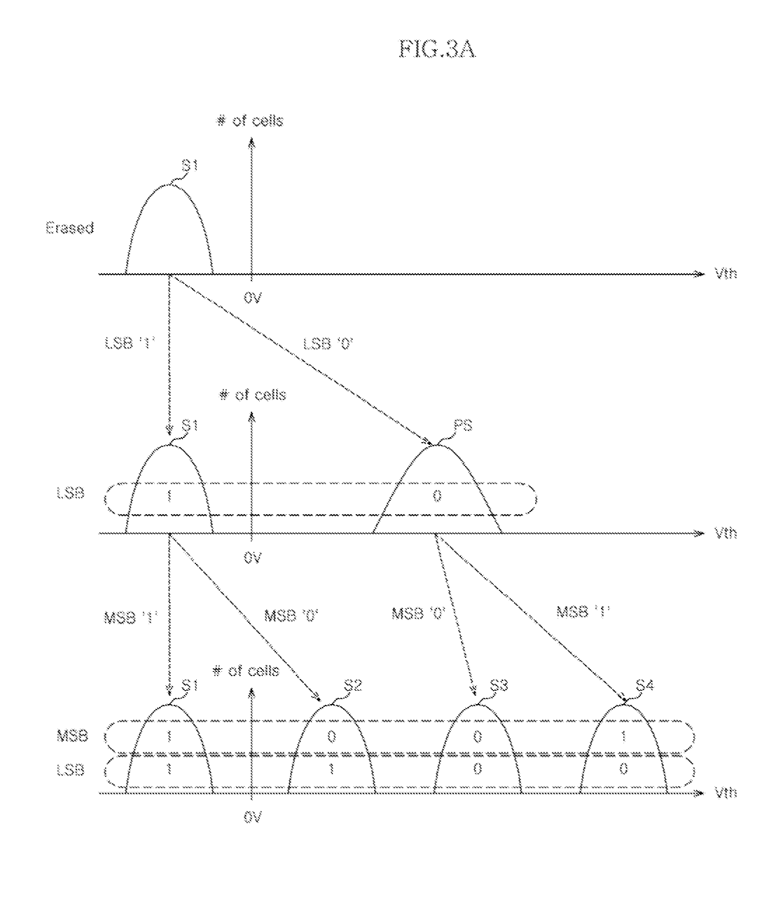

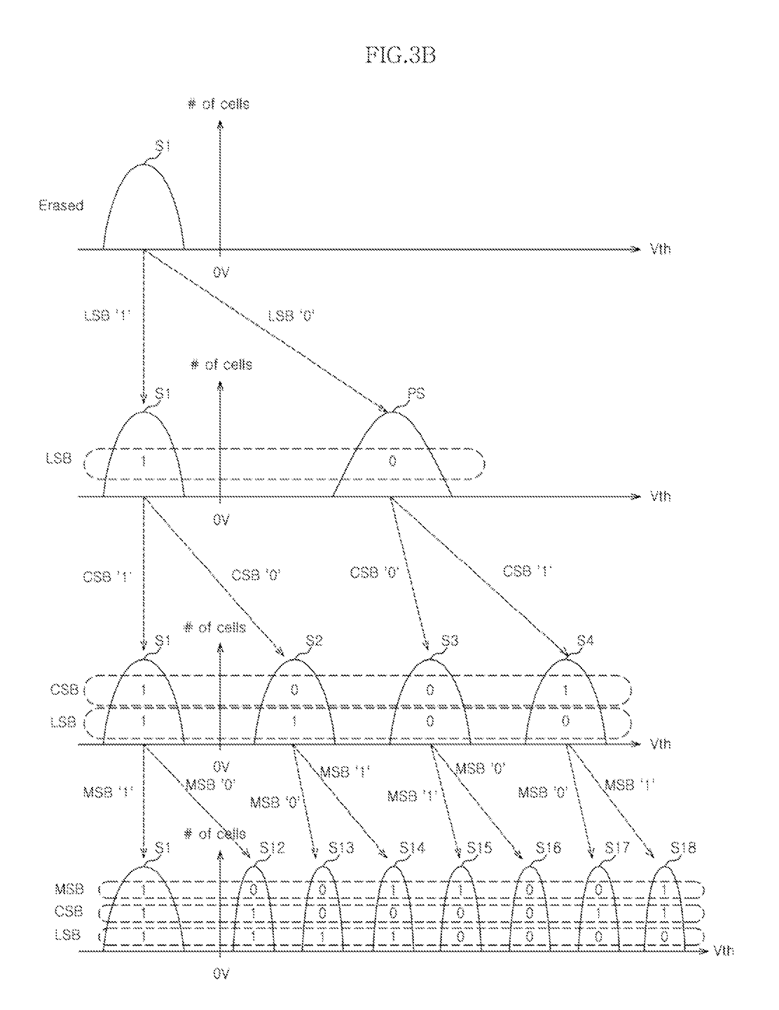

FIGS. 3A and 3B are diagrams to assist in the explanation of changes in threshold voltage distributions of memory cells due to a program operation. Since the program operation may be performed on a page basis through accessing a selected word line, FIGS. 3A and 3B illustrates the threshold voltage distributions of the memory cells MC00 to MC0m coupled to the word line WL0 of FIG. 2. FIG. 3a illustrates where 2-bit data is stored in each memory cell, and FIG. 3b illustrates where 3-bit data is stored in each memory cell.

Data may be identified by a threshold voltage of a memory cell in which the data is stored. That is to say, programming data in a memory cell may mean that the threshold voltage of the memory cell is changed by changing the amount of charge accumulated in the floating gate of the memory cell.

Referring to FIG. 3A, erased memory cells may form a threshold voltage distribution S1.

The memory cells may be programmed with LSB data to form a threshold voltage distribution S1 or a threshold voltage distribution PS depending on the LSB data. The memory cells may form the threshold voltage distribution S1 when LSB data “1” is stored, and form the threshold voltage distribution PS when LSB data “0” is stored. The LSB data stored in the memory cells may be stored in the LSB page.

The memory cells stored with the LSB data may be programmed with MSB data to form threshold voltage distributions S1 to S4 depending on the MSB data. For example, the memory cells stored with the LSB data “1” may form the threshold voltage distribution S1 when MSB data “1” is additionally stored, and form the threshold voltage distribution S2 when MSB data “0” is additionally stored. The MSB data stored in the memory cells may be stored in the MSB page.

Referring to FIG. 38, in the state shown in FIG. 3A, that is, in the state in which 2-bit data is stored in each memory cell, 1-bit data may be additionally stored in each memory cell. The memory cells stored with CSB data may be programmed with MSB data to form threshold voltage distributions S1 to S8 depending on the MSB data.

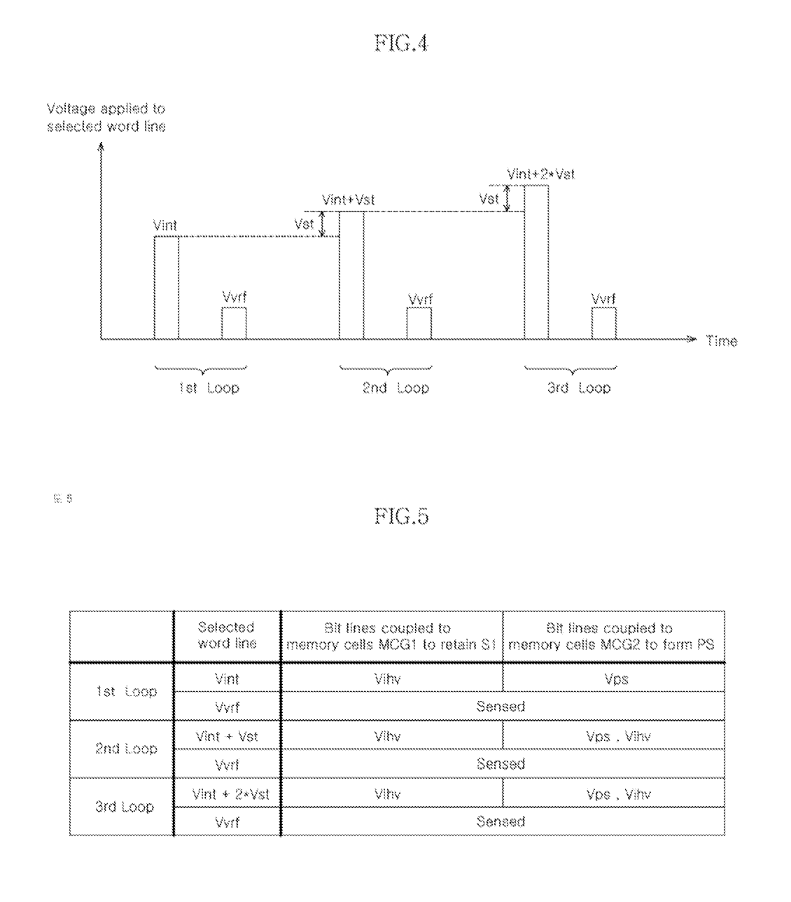

FIG. 4 is a graph illustrating the magnitude of the program and verification voltages applied to a selected word line, over a time, when the control block 110 of FIG. 1 performs a program operation in accordance with the embodiment. FIG. 5 is a table arranging the voltages applied to the selected word line and bit lines when the program operation is performed in accordance with the embodiment. In FIGS. 4 and 5, the program operation may be performed to store LSB data. Target memory cells may retain the threshold voltage distribution S1 of FIG. 3A or newly form the threshold voltage distribution PS of FIG. 3A depending on a value of data to be stored therein.

Referring to FIGS. 4 and 5 together, the control block 110 may perform the program operation by repeatedly performing a program loop for the target memory cells according to the ISPP scheme. Each program loop may include a program voltage application process of applying a program voltage to a selected word line and a program verification process of sensing bit lines while applying a verification voltage to the selected word line. The control block 110 may complete the program operation by repeatedly performing the program loop until data is completely stored in all of the target memory cells. In FIGS. 4 and 5, it is described that the control block 110 completes the program operation by repeatedly performing the program loop, for example, three times.

In a first program loop, the control block 110 may apply a program voltage Vint with an initial value to the selected word line. Further, the control block 110 may apply a program inhibition voltage Vihv to the bit lines coupled to memory cells (hereinafter, referred to as a first memory cell group MCG1) to retain the threshold voltage distribution S1, among the target memory cells, and apply a program permission voltage Vps to the bit lines coupled to memory cells (hereinafter, referred to as a second memory cell group MCG2) to form the threshold voltage distribution PS, among the target memory cells. As a result, the threshold voltages of the memory cells of the first memory cell group MCG1 may be retained, and the threshold voltages of the memory cells of the second memory cell group MCG2 may be increased by the program voltage Vint applied to the gates thereof.

Then, the control block 110 may perform the program verification process by applying a verification voltage Vvrf to the selected word line and sensing the bit lines coupled to the target memory cells. Through the program verification operation, the control block 110 may verify whether data is stored in the target memory cells, and determine each of the target memory cells as a verification pass/fail. When the verification voltage Vvrf is applied to the selected word line, the voltages of the bit lines coupled to the target memory cells may be formed by the values of the data stored in the target memory cells, that is, the threshold voltages of the target memory cells. By sensing the bit lines coupled to the target memory cells, the control block 110 may determine whether the threshold voltage of the second memory cell group MCG2 is larger than the verification voltage Vvrf.

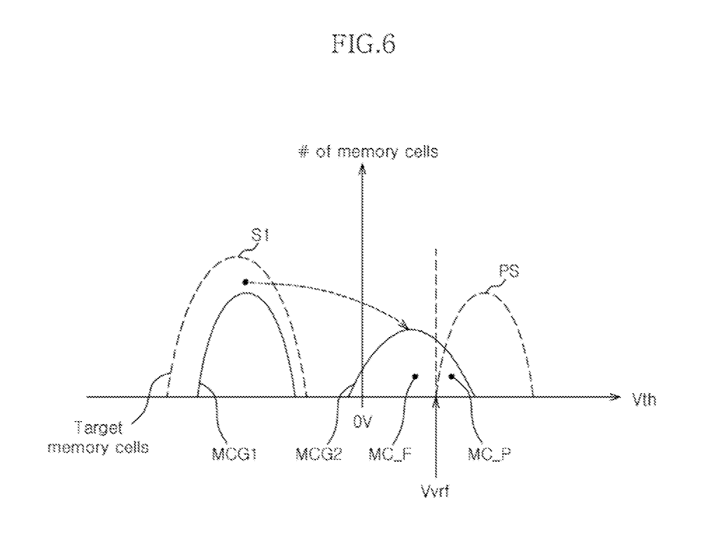

FIG. 6 is a diagram to assist in the explanation of a method for verifying target memory cells. Referring to FIG. 6, the first memory cell group MCG1 among the target memory cells may retain the threshold voltage distribution S1, and the second memory cell group MCG2 among the target memory cells may have an increased threshold voltage distribution as the program voltage Vint is applied thereto. The verification voltage Vvrf may be, for example, a threshold voltage corresponding to the left edge of the threshold voltage distribution PS. Since the target memory cells may have different program speeds, that is, since the target memory cells may have different threshold voltage increase rates even though they are applied with the same program voltage through the gates thereof, the control block 110 may determine only some memory cells MC_P in the second memory cell group MCG2 to form the threshold voltage distribution PS, as a verification pass, and determine the other memory cells MC_F as a verification fail.

Referring again to FIGS. 4 and 5, in a second program loop, the control block 110 may increase the program voltage Vint with the initial value by an increment value Vst, and apply an increased program voltage Vint+Vst to the selected word line. Namely, the control block 110 may increase a program voltage by the increment value Vst from a previous value, each time the program loop is repeated. Further, the control block 110 may apply the program inhibition voltage Vihv to the bit lines coupled to the first memory cell group MCG1 and apply the program inhibition voltage Vihv and the program permission voltage Vps to the bit lines coupled to the second memory cell group MCG2. In the second memory cell group MCG2, the program inhibition voltage Vihv is applied to the bit lines coupled to memory cells (for example, the memory cells MC_P of FIG. 6) which are already verification-passed in the first program loop, and the program permission voltage Vps is applied to the bit lines coupled to memory cells (for example, the memory cells MC_F of FIG. 6) which are verification-failed in the first program loop. As a result, the threshold voltages of the memory cells in the second memory cell group MCG2, which are coupled to the bit lines applied with the program permission voltage Vps, may be increased again by the increased program voltage Vint+Vst applied to the gates thereof.

Then, the control block 110 may perform the program verification process by applying the verification voltage Vvrf to the selected word line and sensing the bit lines coupled to the target memory cells. The control block 110 may determine as a result of the verification that verification-failed memory cells still exist.

In a third program loop, the control block 110 may increase the current program voltage Vint+Vst by the increment value Vst, and apply an increased program voltage Vint+2*Vst to the selected word line. In the second memory cell group MCG2, the control block 110 may apply the program permission voltage Vps to the bit lines coupled to memory cells which are verification-failed in the second program loop, and apply the program inhibition voltage Vihv to the other bit lines. As a result, the threshold voltages of the memory cells in the second memory cell group MCG2, which are coupled to the bit lines applied with the program permission voltage Vps, may be increased further by the increased program voltage Vint+2*Vst applied to the gates thereof.

Then, the control block 110 may perform the program verification process by applying the verification voltage Vvrf to the selected word line and sensing the bit lines coupled to the target memory cells. The control block 110 may determine as a result of the verification that all the memory cells are verification-passed.

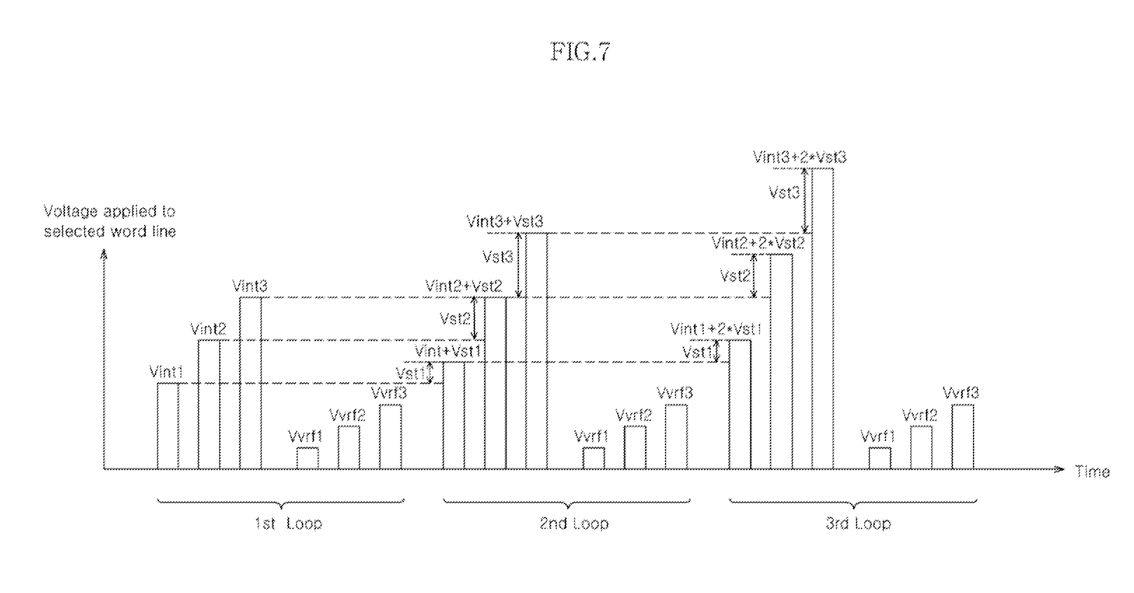

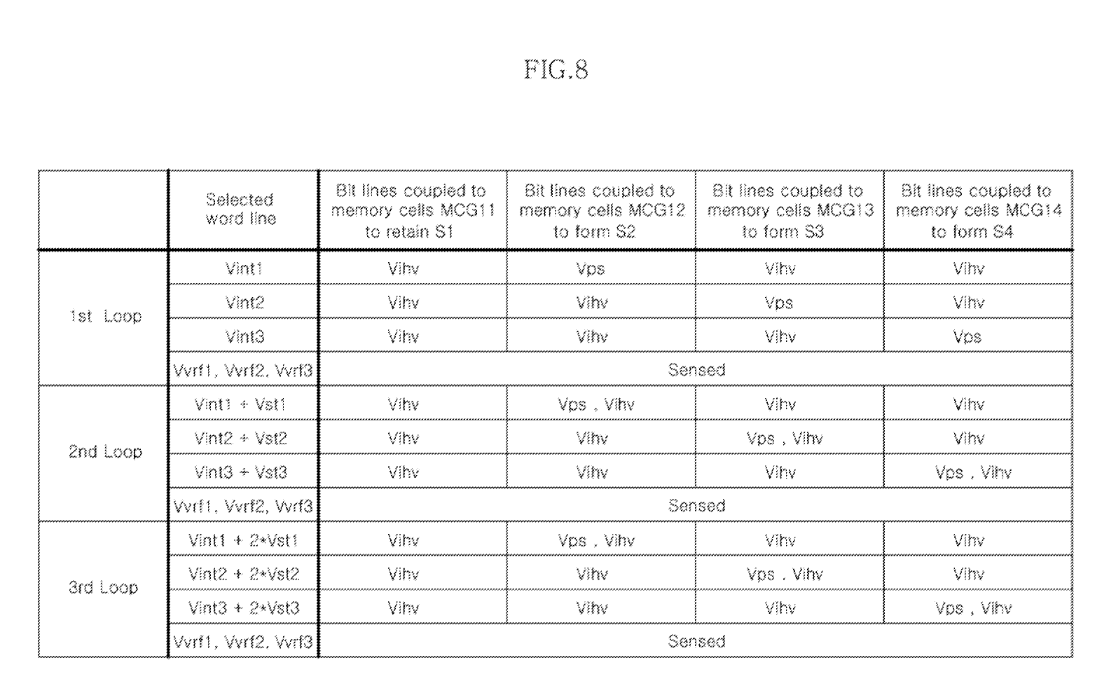

FIG. 7 is a graph illustrating the magnitude of the program and verification voltages applied to a selected word line, over time, when the control block 110 of FIG. 1 performs a program operation in accordance with an embodiment. FIG. 8 is a table arranging the voltages applied to the selected word line and bit lines when the program operation is performed in accordance with an embodiment. In FIGS. 7 and 8, the program operation may be performed to store MSB data. Target memory cells may retain the threshold voltage distribution S1 of FIG. 3A or may form any one of the threshold voltage distributions S2 to S4 of FIG. 3A depending on the data to be stored therein.

Referring to FIGS. 7 and 8 together, as described above, the control block 110 may perform the program operation by repeatedly performing a program loop for the target memory cells according to the ISPP scheme. In each program loop, the control block 110 may sequentially apply a plurality of program voltages (for example, program voltages Vint1, Vint2 and Vint3) to the selected word line, and sequentially apply a plurality of verification voltages (for example, verification voltages Vvrf1, Vvrf2 and Vvrf3) to the selected word line. The plurality of program voltages Vint1, Vint2 and Vint3 may respectively correspond to the threshold voltage distributions S2 to S4 which are to be newly formed by the target memory cells depending on data to be stored in the target memory cells. The plurality of verification voltages Vvrf1, Vvrf2 and Vvrf3 may respectively correspond to the threshold voltage distributions S2 to S4.

In a first program loop, the control block 110 may apply the plurality of program voltages Vint1, Vint2 and Vint3 with initial values to the selected word line. The program voltages Vint1, Vint2 and Vint3 may correspond to the threshold voltage distributions S2 to S4. The program voltage Vint1 may be applied to form the threshold voltage distribution S2, and the program voltage Vint2 may be applied to form the threshold voltage distribution S3, and the program voltage Vint3 may be applied to form the threshold voltage distribution S4.

When applying the program voltages Vint1, Vint2 and Vint3 to the selected word line, the control block 110 may apply a program inhibition voltage Vihv to the bit lines coupled to memory cells (hereinafter, referred to as a first sub memory cell group MCG11) to retain the threshold voltage distribution S1. When applying the program voltage Vint1 corresponding to the threshold voltage distribution S2 to the selected word line, the control block 110 may apply a program permission voltage Vps to the bit lines coupled to memory cells (hereinafter, referred to as a second sub memory cell group MCG12) to form the threshold voltage distribution S2, and apply the program inhibition voltage Vihv to the other bit lines. When applying the program voltage Vint2 corresponding to the threshold voltage distribution S3 to the selected word line, the control block 110 may apply the program permission voltage Vps to the bit lines coupled to memory cells (hereinafter, referred to as a third sub memory cell group MCG13) to form the threshold voltage distribution S3, and apply the program inhibition voltage Vihv to the other bit lines. When applying the program voltage Vint3 corresponding to the threshold voltage distribution S4 to the selected word line, the control block 110 may apply the program permission voltage Vps to the bit lines coupled to memory cells (hereinafter, referred to as a fourth sub memory cell group MCG14) to form the threshold voltage distribution S4, and apply the program inhibition voltage Vihv to the other bit lines.

As a result, the threshold voltage of the first sub memory cell group MCG11 may be retained. The threshold voltage of the second sub memory cell group MCG12 may be increased by the program voltage Vint1 applied to the gates thereof. The threshold voltage of the third sub memory cell group MCG13 may be increased by the program voltage Vint2 applied to the gates thereof. The threshold voltage of the fourth sub memory cell group MCG14 may be increased by the program voltage Vint3 applied to the gates thereof.

Then, the control block 110 may perform a program verification process by sequentially applying the plurality of verification voltages Vvrf1, Vvrf2 and Vvrf3 to the selected word line and sensing the bit lines coupled to the target memory cells each time the verification voltages Vvrf1, Vvrf2 and Vvrf3 are applied. The plurality of verification voltages Vvrf1, Vvrf2 and Vvrf3 may respectively correspond to the threshold voltage distributions S2 to S4. The plurality of verification voltages Vvrf1, Vvrf2 and Vvrf3 may be threshold voltages which respectively correspond to the left edges of the threshold voltage distributions S2 to S4. The control block 110 may determine only some memory cells in the second to fourth sub memory cell groups MCG12, MCG13 and MCG14, as a verification pass, and determine the other memory cells as a verification fail.

In a second program loop, the control block 110 may increase the program voltages Vint1, Vint2 and Vint3 by respective increment values Vst1, Vst2 and Vst3, and sequentially apply increased program voltages Vint1+Vst1, Vint2+Vst2 and Vint3+Vst3 to the selected word line. Namely, the control block 110 may increase program voltages by the respective increment values Vst1, Vst2 and Vst3 from previous values, each time the program loop is repeated. According to an embodiment, the increment values Vst1, Vst2 and Vst3 may be nonuniform and, accordingly, the threshold voltage distributions S1 to S4 to be formed by the target memory cells may have nonuniform widths.

When applying the program voltage Vint1+Vst1 corresponding to the threshold voltage distribution S2 to the selected word line, the control block 110 may apply the program permission voltage Vps to the bit lines coupled to memory cells in the second sub memory cell group MCG12, which are verification-failed in the first program loop, and apply the program inhibition voltage Vihv to the other bit lines. When applying the program voltage Vint2+Vst2 corresponding to the threshold voltage distribution S3 to the selected word line, the control block 110 may apply the program permission voltage Vps to the bit lines coupled to memory cells in the third sub memory cell group MCG13, which are verification-failed in the first program loop, and apply the program inhibition voltage Vihv to the other bit lines. When applying the program voltage Vint3+Vst3 corresponding to the threshold voltage distribution S4 to the selected word line, the control block 110 may apply the program permission voltage Vps to the bit lines coupled to memory cells in the fourth sub memory cell group MCG14, which are verification-failed in the first program loop, and apply the program inhibition voltage Vihv to the other bit lines. As a result, the threshold voltages of the memory cells in the second to fourth sub memory cell groups MCG12, MCG13 and MCG14, which are coupled to the bit lines applied with the program permission voltage Vps, may be increased by the increased program voltages Vint1+Vst1, Vint2+Vst2 and Vint3+Vst3 applied to the gates thereof.

Then, the control block 110 may perform the program verification process by sequentially applying the plurality of verification voltages Vvrf1, Vvrf2 and Vvrf3 to the selected word line and sensing the bit lines coupled to the target memory cells each time the verification voltages Vvrf1, Vvrf2 and Vvrf3 are applied. The control block 110 may determine as a result of the verification that verification-failed memory cells still exist in the second to fourth sub memory cell groups MCG12, MCG13 and MCG14.

In a third program loop, the control block 110 may further increase the program voltages Vint1+Vst1, Vint2+Vst2 and Vint3+Vst3 by the respective increment values Vst1, Vst2 and Vst3, and sequentially apply increased program voltages Vint1+2*Vst1, Vint2+2*Vst2 and Vint3+2*Vst3 to the selected word line. When applying the program voltage Vint1+2*Vst1 corresponding to the threshold voltage distribution S2 to the selected word line, the control block 110 may apply the program permission voltage Vps to the bit lines coupled to memory cells in the second sub memory cell group MCG12, which are verification-failed in the second program loop, and apply the program inhibition voltage Vihv to the other bit lines. When applying the program voltage Vint2+2*Vst2 corresponding to the threshold voltage distribution S3 to the selected word line, the control block 110 may apply the program permission voltage Vps to the bit lines coupled to memory cells in the third sub memory cell group MCG13, which are verification-failed in the second program loop, and apply the program inhibition voltage Vihv to the other bit lines. When applying the program voltage Vint3+2*Vst3 corresponding to the threshold voltage distribution S4 to the selected word line, the control block 110 may apply the program permission voltage Vps to the bit lines coupled to memory cells in the fourth sub memory cell group MCG14, which are verification-failed in the second program loop, and apply the program inhibition voltage Vihv to the other bit lines. As a result, the threshold voltages of the memory cells in the second to fourth sub memory cell groups MCG12, MCG13 and MCG14, which are coupled to the bit lines applied with the program permission voltage Vps, may be further increased by the increased program voltages Vint1+2*Vst1, Vint2+2*Vst2 and Vint3+2*Vst3 applied to the gates thereof.

Then, the control block 110 may perform the program verification process by sequentially applying the plurality of verification voltages Vvrf1, Vvrf2 and Vvrf3 to the selected word line and sensing the bit lines coupled to the target memory cells each time the verification voltages Vvrf1, Vvrf2 and Vvrf3 are applied. The control block 110 may determine as a result of the verification that all the target memory cells are verification-passed.

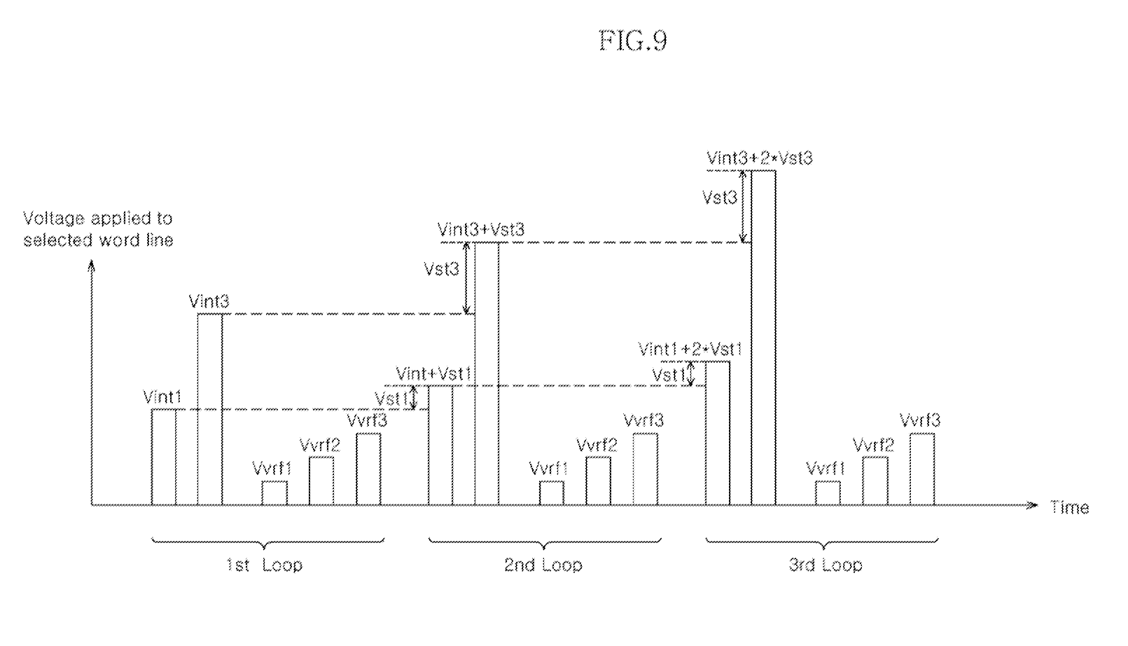

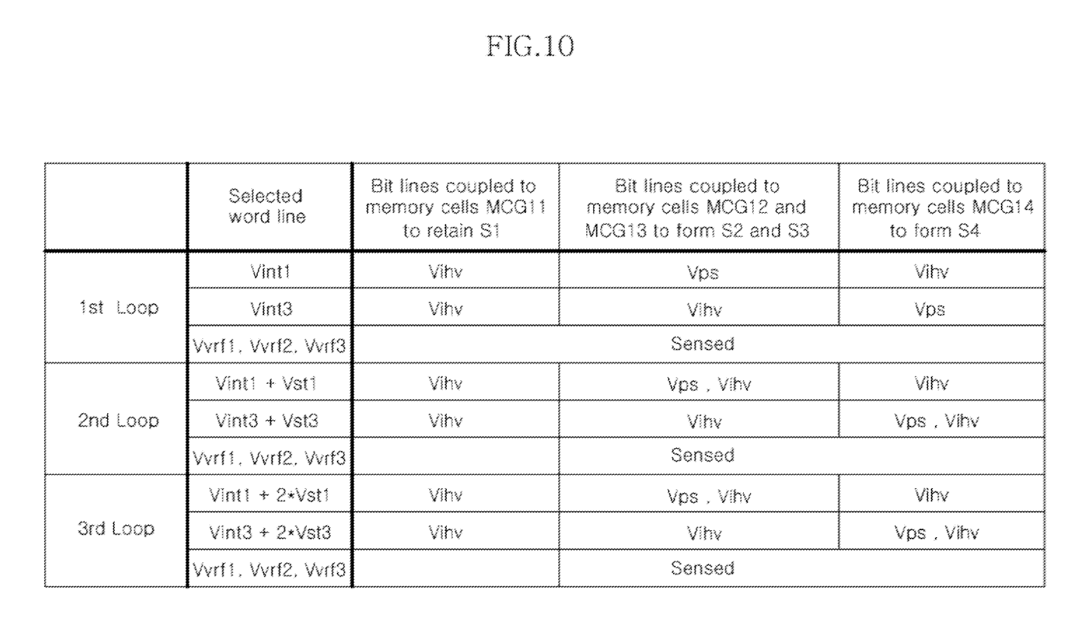

FIG. 9 is a graph illustrating the magnitude of the program and verification voltages applied to a selected word line, over time, when the control block 110 of FIG. 1 performs a program operation in accordance with the embodiment. FIG. 10 is a table arranging the voltages applied to the selected word line and bit lines when the program operation is performed in accordance with the embodiment. In FIGS. 9 and 10, the program operation may be performed to store MSB data. Target memory cells may retain the threshold voltage distribution S1 of FIG. 3A or form any one of the threshold voltage distributions S2 to S4 of FIG. 3A depending on data to be stored therein.

Referring to FIGS. 9 and 10 together, as described above, the control block 110 may perform the program operation by repeatedly performing a program loop for the target memory cells according to the ISPP scheme. In each program loop, the control block 110 may sequentially apply a plurality of program voltages (for example, program voltages Vint1 and Vint3) to the selected word line, and sequentially apply a plurality of verification voltages (for example, verification voltages Vvrf1, Vvrf2 and Vvrf3) to the selected word line. The program voltage Vint1 may correspond to the threshold voltage distributions S2 and S3. The program voltage Vint3 may correspond to the threshold voltage distribution S4. The verification voltages Vvrf1, Vvrf2 and Vvrf3 may respectively correspond to the threshold voltage distributions S2 to S4.

While program voltages correspond to threshold voltage distributions one to one in the embodiment described above with reference to FIGS. 7 and 8, a certain program voltage (that is, the program voltage Vint1) may correspond to a plurality of threshold voltage distributions (that is, the threshold voltage distributions S2 and S3) in the embodiment to be described below with reference to FIGS. 9 and 10. In this case, memory cells to form the threshold voltage distribution S3 may be programmed more slowly since they are applied with a smaller program voltage than the embodiment described above with reference to FIGS. 7 and 8.

In a first program loop, the control block 110 may apply the plurality of program voltages Vint1 and Vint3 with respective initial values to the selected word line. The program voltage Vint1 may be applied to form the threshold voltage distributions S2 and S3, and the program voltage Vint3 may be applied to form the threshold voltage distribution S4.

When applying the program voltages Vint1 and Vint3 to the selected word line, the control block 110 may apply a program inhibition voltage Vihv to the bit lines coupled to a first sub memory cell group MCG11 to retain the threshold voltage distribution S1. When applying the program voltage Vint1 corresponding to the threshold voltage distributions S2 and S3 to the selected word line, the control block 110 may apply a program permission voltage Vps to second and third sub memory cell groups MCG12 and MCG13 to form the threshold voltage distributions S2 and S3, and apply the program inhibition voltage Vihv to the other bit lines. When applying the program voltage Vint3 corresponding to the threshold voltage distribution S4 to the selected word line, the control block 110 may apply the program permission voltage Vps to a fourth sub memory cell group MCG14 to form the threshold voltage distribution S4, and apply the program inhibition voltage Vihv to the other bit lines.

As a result, the threshold voltage of the first sub memory cell group MCG11 may be retained. The threshold voltages of the second and third sub memory cell groups MCG12 and MCG13 may be increased by the program voltage Vint1 applied to the gates thereof. The threshold voltage of the fourth sub memory cell group MCG14 may be increased by the program voltage Vint3 applied to the gates thereof.

Then, the control block 110 may perform the program verification process by sequentially applying the plurality of verification voltages Vvrf1, Vvrf2 and Vvrf3 to the selected word line and sensing the bit lines coupled to the target memory cells each time the verification voltages Vvrf1, Vvrf2 and Vvrf3 are applied. The verification voltages Vvrf1, Vvrf2 and Vvrf3 may respectively correspond to the threshold voltage distributions S2 to S4. The plurality of verification voltages Vvrf1, Vvrf2 and Vvrf3 may be threshold voltages which respectively correspond to the left edges of the threshold voltage distributions S2 to S4. The control block 110 may determine only some memory cells in the second to fourth sub memory cell groups MCG12, MCG13 and MCG14, as a verification pass, and determine the other memory cells as a verification fail.

In a second program loop, the control block 110 may increase the program voltages Vint1 and Vint3 by respective increment values Vst1 and Vst3, and sequentially apply increased program voltages Vint1+Vst1 and Vint3+Vst3 to the selected word line. Namely, the control block 110 may increase program voltages by the respective increment values Vst1 and Vst3 from previous values, each time the program loop is repeated. According to an embodiment, the increment values Vst1 and Vst3 may be nonuniform and, accordingly, the threshold voltage distributions S1 to S4 to be formed by the target memory cells may have nonuniform widths.

When applying the program voltage Vint1+Vst1 corresponding to the threshold voltage distributions S2 and S3 to the selected word line, the control block 110 may apply the program permission voltage Vps to the bit lines coupled to memory cells in the second and third sub memory cell groups MCG12 and MCG13, which are verification-failed in the first program loop, and apply the program inhibition voltage Vihv to the other bit lines. When applying the program voltage Vint3+Vst3 corresponding to the threshold voltage distribution S4 to the selected word line, the control block 110 may apply the program permission voltage Vps to the bit lines coupled to memory cells in the fourth sub memory cell group MCG14, which are verification-failed in the first program loop, and apply the program inhibition voltage Vihv to the other bit lines. As a result, the threshold voltages of the memory cells in the second to fourth sub memory cell groups MCG12, MCG13 and MCG14, which are coupled to the bit lines applied with the program permission voltage Vps, may be increased by the increased program voltages Vint1+Vst1 and Vint3+Vst3 applied to the gates thereof.

Then, the control block 110 may perform the program verification process by sequentially applying the plurality of verification voltages Vvrf1, Vvrf2 and Vvrf3 to the selected word line and sensing the bit lines coupled to the target memory cells each time the verification voltages Vvrf1, Vvrf2 and Vvrf3 are applied. The control block 110 may determine as a result of the verification that verification-failed memory cells still exist in the second to fourth sub memory cell groups MCG12, MCG13 and MCG14.

In a third program loop, the control block 110 may further increase the program voltages Vint1+Vst1 and Vint3+Vst3 by the respective increment values Vst1 and Vst3, and sequentially apply increased program voltages Vint1+2*Vst1 and Vint3+2*Vst3 to the selected word line. When applying the program voltage Vint1+2*Vst1 corresponding to the threshold voltage distributions S2 and S3 to the selected word line, the control block 110 may apply the program permission voltage Vps to the bit lines coupled to memory cells in the second and third sub memory cell groups MCG12 and MCG13, which are verification-failed in the second program loop, and apply the program inhibition voltage Vihv to the other bit lines. When applying the program voltage Vint3+2*Vst3 corresponding to the threshold voltage distribution S4 to the selected word line, the control block 110 may apply the program permission voltage Vps to the bit lines coupled to memory cells in the fourth sub memory cell group MCG14, which are verification-failed in the second program loop, and apply the program inhibition voltage Vihv to the other bit lines. As a result, the threshold voltages of the memory cells in the second to fourth sub memory cell groups MCG12, MCG13 and MCG14, which are coupled to the bit lines applied with the program permission voltage Vps, may be further increased by the increased program voltages Vint1+2*Vst1 and Vint3+2*Vst3 applied to the gates thereof.

Then, the control block 110 may perform the program verification process by sequentially applying the plurality of verification voltages Vvrf1, Vvrf2 and Vvrf3 to the selected word line and sensing the bit lines coupled to the target memory cells each time the verification voltages Vvrf1, Vvrf2 and Vvrf3 are applied. The control block 110 may determine as a result of the verification that all the target memory cells are verification-passed.

In summary, according to the embodiment, an increment value corresponding to a highest program voltage among a plurality of program voltages may be highest among a plurality of increment values. Further, the other increment values may be the same. In this case, a highest threshold voltage distribution among threshold voltage distributions to be formed by target memory cells may have a widest width, and the other threshold voltage distributions may have the same width.

FIG. 11 is a flow chart to assist in explaining a method for operating the nonvolatile memory apparatus 100 in accordance with an embodiment. FIG. 11 illustrates a method for driving a selected word line when the control block 110 performs a program operation.

At step S110, the control block 110 may receive a program command for a plurality of target memory cells which are coupled to a selected word line and are respectively coupled to different bit lines, from an external device.

At step S120, the control block 110 may sequentially apply one or more program voltages to the selected word line. The one or more program voltages may correspond to one or more threshold voltage distributions to be formed by the target memory cells depending on data to be stored in the target memory cells. When applying the program voltages, the control block 110 may apply a program permission voltage to selected bit lines among the bit lines coupled to the target memory cells, and apply a program prohibition voltage to the other bit lines. The selected bit lines may be bit lines which are coupled to memory cells to form a threshold voltage distribution corresponding to a program voltage being applied to the selected word line.

At step S130, the control block 110 may sequentially apply one or more verification voltages to the selected word line. The one or more verification voltages may correspond to the threshold voltage distributions to be formed by the target memory cells depending on data to be stored in the target memory cells. The control block 110 may sense the bit lines coupled to the target memory cells while applying the verification voltages.

At step S140, the control block 110 may determine whether all the target memory cells are verification-passed, based on a result of sensing the bit lines. When it is determined based on the result of sensing the bit lines that data is stored in the target memory cells, the control block 110 may determine that the target memory cells are verification-passed. When all the target memory cells are verification-passed, the process may be ended. When not all of the target memory cells are verification-passed, the process may proceed to step S150.

At the step S150, the control block 110 may increase the one or more program voltages by respective increment values. The increment values may be nonuniform. As a result, the threshold voltage distributions to be formed by the target memory cells may have nonuniform widths.

Then, at the step S120, the control block 110 may sequentially apply one or more increased program voltages to the selected word line. In summary, the control block 110 may repeat a program loop including the program voltage applying step (the step S120) and the program verifying step (the step S130) until it is determined at step S140 that all the target memory cells are verification-passed, and increase the program voltages by the respective increment values each time the program loop is repeated.

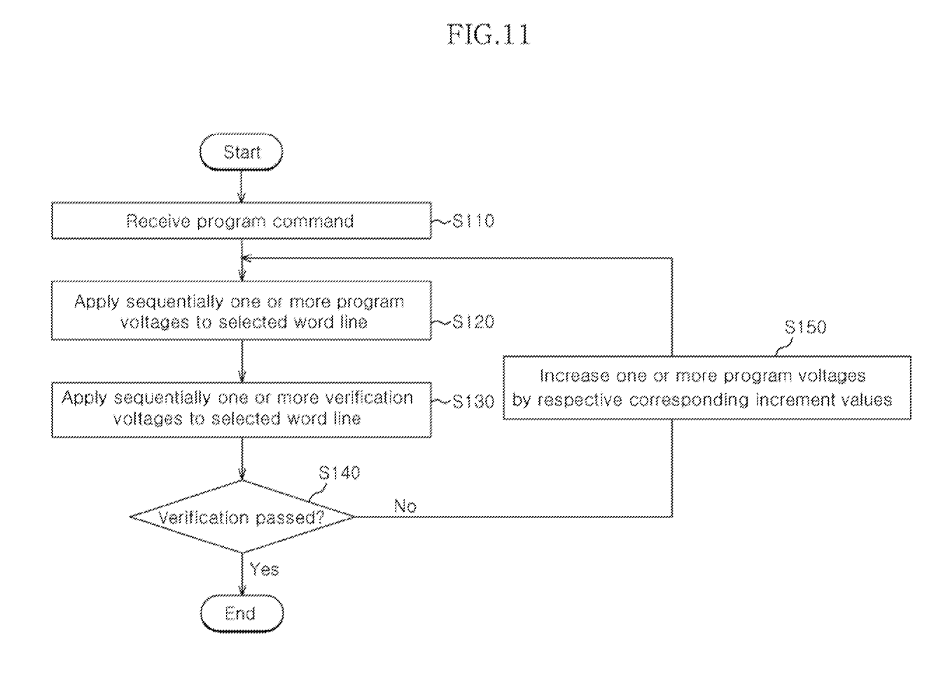

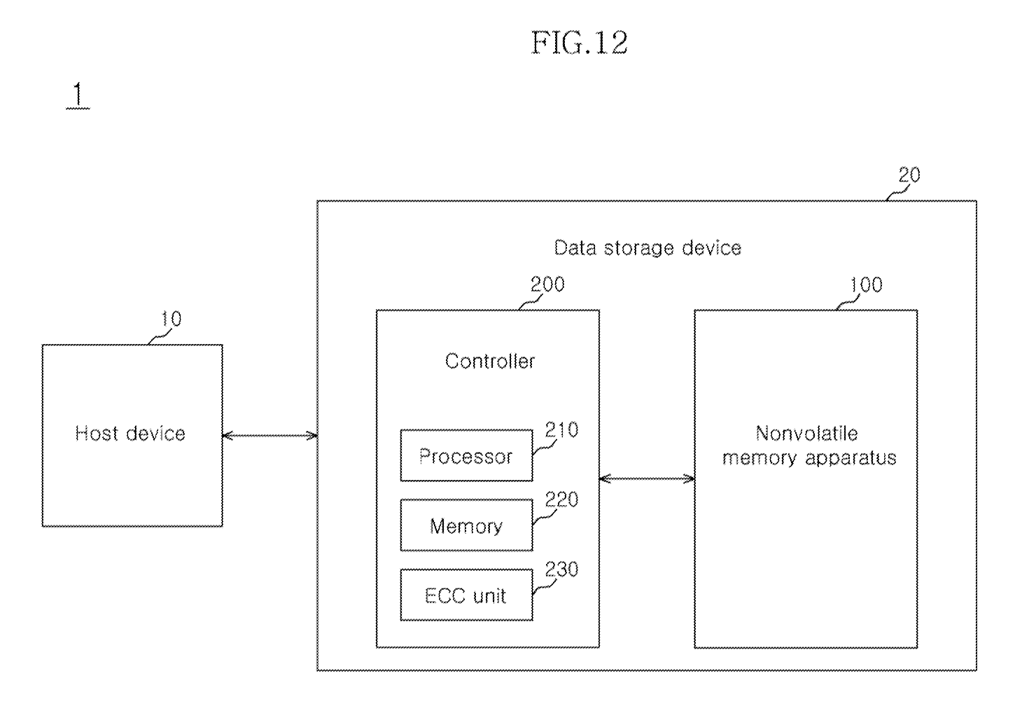

FIG. 12 is a block diagram illustrating a data processing system 1 including the nonvolatile memory apparatus 100 in accordance with an embodiment.

The data processing system 1 may include a host device 10 and a data storage device 20.

The host device 10 as an electronic device capable of processing data and may include a computer, a digital camera or a mobile phone.

The data storage device 20 may be configured to store the data provided from the host device 10 in response to a program request from the host device 10. Also, the data storage device 20 may be configured to provide stored data to the host device 10 in response to a read request from the host device 10. The data storage device 20 may be manufactured in a detachable form and coupled to the host device 10 or may be embedded in the host device 10.

The data storage device 20 may be configured as a personal computer memory card international association (PCMCIA) card, a compact flash (CF) card, a smart media card, a memory stick, a multimedia card in the form of an MMC, an eMMC, an RS-MMC and an MMC-micro, a secure digital card in the form of an SD, a mini-SD and a micro-SD, a universal flash storage (UFS), or a solid state drive (SSD).

The data storage device 20 may include a controller 200 and a nonvolatile memory apparatus 100. The nonvolatile memory apparatus 100 may be configured in substantially the same way as the nonvolatile memory apparatus 100 shown in FIG. 1.

The controller 200 may include a processor 210, a memory 220, and an error correction code (ECC) unit 230.

The processor 210 may control the general operations of the data storage device 20. The processor 210 may control the program operation or the read operation of the nonvolatile memory apparatus 100 in response to the program request or the read request from the host device 10. The processor 210 may generate a command for controlling the operation of the nonvolatile memory apparatus 100, and provide the generated command to the nonvolatile memory apparatus 100. When the ECC unit 230 is not able to correct the error included in the data read from the nonvolatile memory apparatus 100, the processor 210 may control the nonvolatile memory apparatus 100 to perform again the read operation based on a new read voltage. The processor 210 may drive a software program for controlling the operation of the data storage device 20, on the memory 220.

The memory 220 may serve as a working memory, a buffer memory or a cache memory of the processor 210. The memory 220 as a working memory may store software programs and various program data to be driven by the processor 210. The memory 220 as a buffer memory may buffer the data transmitted between the host device 10 and the nonvolatile memory apparatus 100. The memory 220 as a cache memory may temporarily store cache data.

The ECC unit 230 may encode data before the data is stored in the nonvolatile memory apparatus 100 at the program request from the host device 10, such that it is possible to subsequently determine whether an error has occurred in the data and correct it. When encoded data is read from the nonvolatile memory apparatus 100 at the read request from the host device 10, the ECC unit 230 may decode the encoded data and detect and correct errors in the corresponding data.

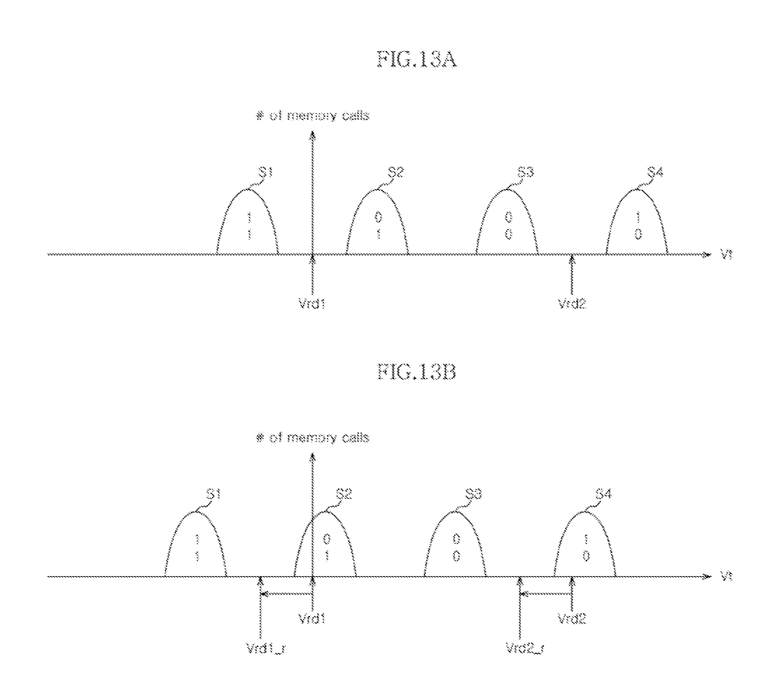

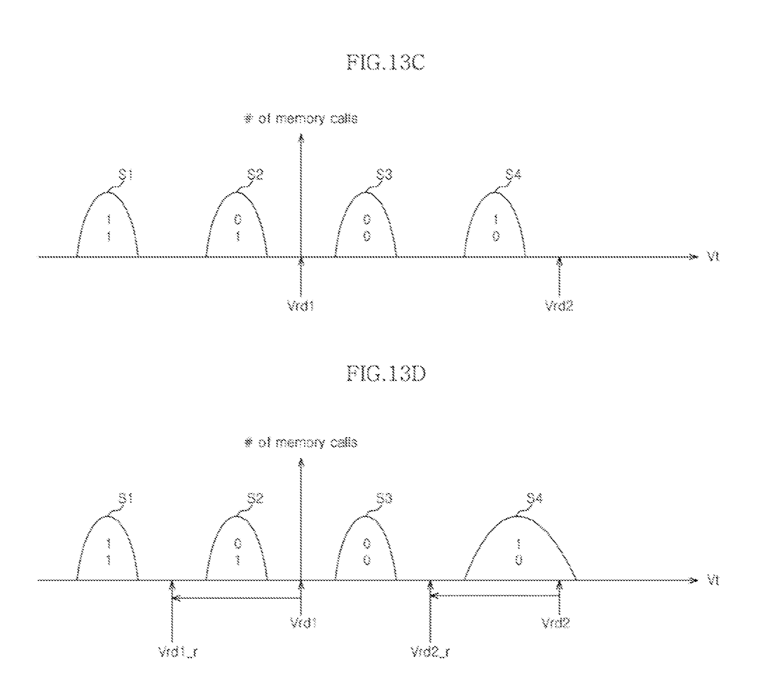

FIGS. 13A to 13D are diagrams to assist in the explanation of the effects of the embodiments.

FIG. 13A illustrates threshold voltage distributions S1 to S4 formed according to the conventional art and read voltages Vrd1 and Vrd2 for reading MSB data. When a read command for the MSB data stored in target memory cells is received from the controller 200, the control block 110 may apply the read voltages Vrd1 and Vrd2 to a selected word line to which the target memory cells are coupled. When the read voltages Vrd1 and Vrd2 are applied to the selected word line, the voltages of the bit lines coupled to the target memory cells may be formed by the values of the data stored in the target memory cells, that is, the threshold voltages of the target memory cells. Accordingly, the control block 110 may read the data stored in the target memory cells by sensing the bit lines while applying the read voltages Vrd1 and Vrd2 to the selected word line.

The control block 110 may determine that data “1” is stored in a memory cell which has a threshold voltage smaller than the read voltage Vrd1 or larger than the read voltage Vrd2, and determine that data “0” is stored in a memory cell which has a threshold voltage larger than the read voltage Vrd1 and smaller than the read voltage Vrd2. In the threshold voltage distributions of FIG. 13A, all data may be output without errors. The data outputted without any errors may be properly decoded by the ECC unit 230.

Referring to FIG. 13B, when target memory cells are influenced by surrounding circumstances, for example, high temperature, the threshold voltage distributions S1 to S4 may move leftward. When the control block 110 reads the data stored in the target memory cells by using the existing read voltages Vrd1 and Vrd2, that data that is read may include errors. For example, data “1” may be outputted as an error from some of the memory cells which form the threshold voltage distribution S2, that is, the memory cells which have a threshold voltage smaller than the read voltage Vrd1. The data including an error may be decoded by the ECC unit 230. When the ECC unit 230 fails in decoding, the processor 210 may control the control block 110 to perform the read operation again based on new read voltages Vrd1_r and Vrd2_r, whereby it is possible to acquire data without an error.

Referring to FIG. 13C, when target memory cells are more greatly affected by operating conditions, the threshold voltage distributions S1 to S4 may move even more to the left. When the control block 110 reads the data stored in the target memory cells by using the existing read voltages Vrd1 and Vrd2, the LSB data stored in the target memory cells may be output without any errors. As a result of decoding the LSB data by the ECC unit 230, the processor 210 may acquire the wrong data even without performing another read operation.

Referring to FIG. 13D, threshold voltage distributions S1 to S4 formed according to the embodiment and read voltages Vrd1 and Vrd2 for reading MSB data are illustrated. According to the embodiment, the threshold voltage distributions S11 to S4 may have nonuniform widths, for example, the threshold voltage distribution S4 may have a width larger than the remaining threshold voltage distributions S1 to S3. When the increment values Vst1 and Vst2 are the same and the increment value Vst3 is larger than the increment values Vst1 and Vst2 in FIG. 8, as shown in FIG. 13D, the threshold voltage distribution S4 may have a greater width than the remaining threshold voltage distributions S1 to S3. When the control block 110 reads the data stored in the target memory cells by using the existing read voltages Vrd1 and Vrd2, the LSB data stored in the target memory cells may not be outputted properly even in the large leftward shift of the threshold voltage distributions S1 to S4. Therefore, the ECC unit 230 may fail in decoding, and the processor 210 may control the control block 110 to perform another read operation based on new read voltages Vrd1_r and Vrd2_r, whereby it is possible to acquire data without any errors.

As is apparent from the above descriptions, according to the embodiments, a nonvolatile memory apparatus may perform a program operation such that the threshold voltage distributions formed by target memory cells have nonuniform widths, whereby it is possible to provide improved data reliability.

While various embodiments have been described above, it will be understood to those skilled in the art that the embodiments described are examples only. Accordingly, the semiconductor apparatus and the operating method thereof described herein should not be limited based on the described embodiments.

What is claimed is:

1. A nonvolatile memory apparatus comprising:
a plurality of memory cells coupled to a word line and respectively coupled to different bit lines; and
a control block suitable for applying one or more program voltages to the word line in a program loop, and increasing the one or more program voltages in increments each time the program loop is repeated,
wherein at least one of the increments is different.

2. The nonvolatile memory apparatus according to claim 1, wherein the one or more program voltages correspond to one or more threshold voltage distributions that are formed by the plurality of memory cells.

3. The nonvolatile memory apparatus according to claim 1,
wherein the control block applies a program permission voltage to selected bit lines, and applies a program inhibition voltage to other bit lines, and
wherein the selected bit lines are coupled to memory cells that form a threshold voltage distribution corresponding to a program voltage being applied to the word line.

4. The nonvolatile memory apparatus according to claim 1, wherein an increment corresponding to a highest program voltage is highest among the increments.

5. The nonvolatile memory apparatus according to claim 1, wherein the control block performs a program verification process in the program loop by sequentially applying one or more verification voltages to the word line and sensing the bit lines each time the verification voltages are applied.

6. The nonvolatile memory apparatus according to claim 5, wherein the one or more verification voltages correspond to one or more threshold voltage distributions which are formed by the plurality of memory cells.

7. The nonvolatile memory apparatus according to claim 5, wherein the control block repeatedly performs the program loop based on a result of performing the program verification process.

8. The nonvolatile memory apparatus according to claim 1, wherein the control block comprises:
a register suitable for storing initial values of the one or more program voltages and the increments.

9. A method for operating a nonvolatile memory apparatus, comprising:
receiving a program command for a plurality of memory cells coupled to a word line and respectively coupled to different bit lines; and
performing a program loop by sequentially applying one or more program voltages to the word line,
wherein the one or more program voltages are increased in Increments each time the program loop is performed, and
wherein at least one of the increments are different.

10. The method according to claim 9, wherein the one or more program voltages correspond to one or more threshold voltage distributions formed by the plurality of memory cells.

11. The method according to claim 9, wherein the performing of the program loop comprises:
applying a program permission voltage to selected bit lines; and
applying a program inhibition voltage to other bit lines,
wherein the selected bit lines are coupled to memory cells, which are to form a threshold voltage distribution corresponding to a program voltage being applied to the word line.

12. The method according to claim 9, wherein an increment corresponding to a highest program voltage is highest among the increments.

13. The method according to claim 9, wherein the performing of the program loop comprises:
sequentially applying one or more verification voltages to the word line;
sensing the bit lines each time the verification voltages are applied; and
determining whether data are stored in the plurality of memory cells, based on a result of the sensing of the bit lines.

14. The method according to claim 13, wherein the one or more verification voltages correspond to one or more threshold voltage distributions which are formed by the plurality of memory cells.

15. A nonvolatile memory apparatus comprising:
a plurality of memory cells coupled to a word line and respectively coupled to different bit lines; and
a control block suitable for applying one or more program voltages to the word line in a program loop, and programming the plurality of memory cells to form one or more threshold voltage distributions,
wherein the one or more threshold voltage distributions have different widths.

16. The nonvolatile memory apparatus according to claim 15, wherein the control block increases the one or more program voltages in increments that vary each time the program loop is repeated,
wherein an increment corresponding to a highest program voltage is highest among the increments.

17. The nonvolatile memory apparatus according to claim 15,
wherein the control block applies a program permission voltage to selected bit lines, and applies a program inhibition voltage to other bit lines, and
wherein the selected bit lines are coupled to memory cells, which are to form a threshold voltage distribution corresponding to a program voltage being applied to the word line.

18. The nonvolatile memory apparatus according to claim 15, wherein the control block performs a program verification process in the program loop by sequentially applying one or more verification voltages to the word line and sensing the bit lines each time the verification voltages are applied.

19. The nonvolatile memory apparatus according to claim 18, wherein the one or more verification voltages correspond to one or more threshold voltage distributions which are formed by the plurality of memory cells.

20. The nonvolatile memory apparatus according to claim 18, wherein the control block repeatedly performs the program loop based on a result of performing the program verification process.
